(19) United States
(12) Patent Application Publication
(10) Pub. No.: US 2024/0266144 A1
(43) Pub. Date: Aug. 8, 2024

(54) SUBSTRATE PROCESSING APPARATUS AND SUBSTRATE PROCESSING METHOD USING THE SAME

(71) Applicant: SAMSUNG ELECTRONICS CO., LTD., Suwon-si (KR)

(72) Inventors: JAEWON JEONG, Suwon-si (KR); KYEONGTEA BANG, Suwon-si (KR); SEUNGBO SHIM, Suwon-si (KR); NAOHIKO OKUNISHI, Suwon-si (KR); KIHWAN JANG, Suwon-si (KR); KYUNG-SUN KIM, Suwon-si (KR)

(73) Assignee: SAMSUNG ELECTRONICS CO., LTD., Suwon-si (KR)

(21) Appl. No.: 18/238,874

(22) Filed: Aug. 28, 2023

(30) Foreign Application Priority Data
Feb. 2, 2023 (KR) 10-2023-0014302

(51) Int. Cl. H01J 37/32

(52) U.S. Cl. CPC H01J 37/3211; H01J 2237/327; H01L 21/3065

(57) ABSTRACT

A substrate processing apparatus including a process chamber providing a process space and a plasma generator on the process chamber. The plasma generator may include an inner antenna ring; an outer antenna ring outside of spaced apart from the inner antenna ring, and a floating ring between the inner antenna ring and the outer antenna ring. The floating ring may be electrically isolated from the inner antenna ring and the outer antenna ring.

### CROSS-REFERENCE TO RELATED APPLICATION

This application claims priority under 35 U.S.C. § 119 to Korean Patent Application No. 10-2023-0014302, filed on Feb. 2, 2023, in the Korean Intellectual Property Office, the disclosure of which is incorporated by reference herein in its entirety.

### BACKGROUND

The present disclosure relates to a substrate processing apparatus and a substrate processing method using the same, and in particular, to a substrate processing apparatus, which is configured to improve uniformity of plasma, and a substrate processing method using the same.

A semiconductor device may be fabricated through various processes. For example, a semiconductor device may be fabricated by performing a photolithography process, an etching process, and a deposition process on a wafer. Various fluidic materials are used in these processes. Plasma may be used in an etching process and/or a deposition process. An electrode is used to produce and/or control the plasma, during the process.

### SUMMARY

Example embodiments provide a substrate processing apparatus, which is configured to improve uniformity of plasma, and a substrate processing method using the same.

Further, example embodiments provide an a substrate processing apparatus, which is configured to uniformly perform a fabrication process on a substrate, and a substrate processing method using the same.

Further still, example embodiments provide an a substrate processing apparatus, which is adaptively used to various processes, and a substrate processing method using the same.

According to an aspect of an example embodiment, a substrate processing apparatus includes: a process chamber providing a process space; and a plasma generator on the process chamber, wherein the plasma generator includes: an inner antenna ring; an outer antenna ring outside of and spaced apart from the inner antenna ring; and a floating ring between the inner antenna ring and the outer antenna ring, and the floating ring is electrically isolated from the inner antenna ring and the outer antenna ring.

According to an aspect of an example embodiment, a substrate processing apparatus includes: a process chamber; and a plasma generator on the process chamber, wherein the plasma generator includes: an inner antenna ring; an outer antenna ring outside of the inner antenna ring; a floating ring between and electrically isolated from the inner antenna ring and the outer antenna ring; first power delivery rod connected to the inner antenna ring and configured to deliver a first RF power to the inner antenna ring; and a second power delivery rod connected to the outer antenna ring and configured to deliver a second RF power to the outer antenna ring, and the floating ring has a continuous ring shape.

According to an aspect of an example embodiment, a substrate processing apparatus includes: a process chamber providing a process space; and a plasma generator provided above the process space, wherein the plasma generator includes: an inner antenna ring centered on a first axis extending in a first direction; an outer antenna ring outside of the inner antenna ring and centered on a second axis extending in the first direction; and a floating ring between the inner antenna ring and the outer antenna ring and centered on a third axis extending in the first direction, and the floating ring comprises a revolving body centered on the third axis.

According to an aspect of an example embodiment, a substrate processing method includes: loading a substrate in a substrate processing apparatus; supplying a process gas into the substrate processing apparatus; generating plasma on the substrate using a plasma generator; and treating the substrate with the plasma, wherein the plasma generator includes: an inner antenna ring; an outer antenna ring outside of and spaced apart from the inner antenna ring; and a floating ring between the inner antenna ring and the outer antenna ring, and the generating plasma on the substrate includes: applying a first radio frequency (RF) power to the inner antenna ring; and applying a second RF power to the outer antenna ring.

### BRIEF DESCRIPTION OF THE DRAWINGS

The above and other aspects and features will be more apparent from the following description of one or more example embodiments taken in conjunction with the accompanying drawings, in which:

FIG. 1 is a sectional view illustrating a substrate processing apparatus according to one or more example embodiments;

FIG. 2 is an enlarged sectional view illustrating a portion ‘X’ of FIG. 1 according to one or more example embodiments;

FIG. 3 is an enlarged sectional view illustrating a portion ‘Y’ of FIG. 1 according to one or more example embodiments;

FIG. 4 is an enlarged sectional view illustrating a portion ‘Z’ of FIG. 3 according to one or more example embodiments;

FIG. 5 is a perspective view partially illustrating a plasma generating portion according to one or more example embodiments;

FIG. 6 is a plan view illustrating a plasma generating portion according to one or more example embodiments;

FIG. 7 is an enlarged plan view illustrating ‘P’ of FIG. 6 according to one or more example embodiments;

FIG. 8 is a flow chart illustrating a substrate processing method according to one or more example embodiments;

FIGS. 9, 10, 11, 12, 13 and 14 are diagrams illustrating a substrate processing method according to the flow chart of FIG. 8 according to one or more example embodiments;

FIGS. 15 and 16 are graphs showing technical effects that can be obtained by a substrate processing apparatus according to one or more example embodiments; and

FIG. 17 is a sectional view illustrating a portion of a substrate processing apparatus according to one or more example embodiments.

### DETAILED DESCRIPTION

One or more example embodiments will be described more fully with reference to the accompanying drawings, in which one or more example embodiments are shown. Like reference numerals in the drawings denote like elements, and thus duplicate descriptions are omitted.

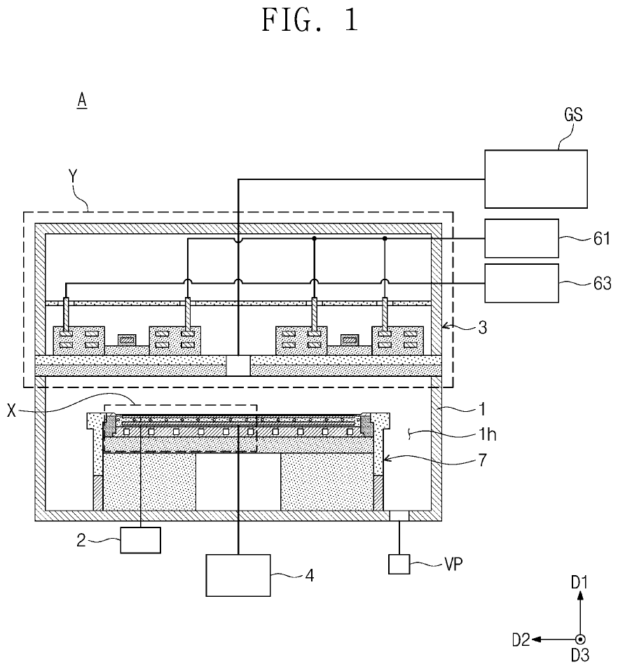

FIG. 1 is a sectional view illustrating a substrate processing apparatus according to one or more example embodiments.

In one or more example embodiments, the reference numbers D1, D2, and D3 may be used to denote a first direction, a second direction, and a third direction, respectively, which are not parallel to each other. The first direction D1 may be referred to as a vertical direction. Each of the second and third directions D2 and D3 may be referred to as a horizontal direction.

Referring to FIG. 1, a substrate processing apparatus A may be provided. The substrate processing apparatus A may be configured to perform a specific process on a substrate. The substrate may be a silicon wafer, but one or more example embodiments are not limited to this example embodiment. For example, the substrate processing apparatus A may be configured to perform an etching process on the substrate. According to one or more example embodiments, the substrate processing apparatus A may be configured to generate plasma. More specifically, an induction current, which is produced when an electric power is applied to a coil, may be used to generate plasma in the substrate processing apparatus A. That is, the substrate processing apparatus A may be an inductively-coupled plasma (ICP) apparatus. According to one or more example embodiments, the substrate processing apparatus A may include a process chamber 1, a plasma generating portion or plasma generator 3, a stage 7, a direct current (DC) power generating unit 2, a first radio-frequency (RF) power generating unit 61, a second RF power generating unit 63, a third RF power generating unit 4, a gas supplying device GS, and a vacuum pump VP.

The process chamber 1 may be configured to provide a process space 1h. In the process space 1h, a fabrication process may be performed on the substrate. The process space 1h may be isolated from an external space. During the fabrication process on the substrate, the process space 1h may be in a substantially vacuum state. The process chamber 1 may have a cylindrical shape, but one or more example embodiments are not limited to this example embodiment.

The plasma generating portion 3 may be placed on the process chamber 1. The plasma generating portion 3 may be configured to generate the plasma. More specifically, if an RF power is applied to the plasma generating portion 3, at least a portion of a process gas in the process space 1h may form the plasma. The plasma generating portion 3 will be described in more detail below according to one or more example embodiments.

The stage 7 may be placed in the process chamber 1. For example, the stage 7 may be placed in the process space 1h. The stage 7 may be configured to support and/or hold the substrate. The fabrication process may be performed on the substrate, which is loaded on the stage 7. The stage 7 will be described in more detail below according to one or more example embodiments.

The DC power generating unit 2 may be configured to apply DC power to the stage 7. The DC power from the DC power generating unit 2 may be used to fasten the substrate to a specific position on the stage 7.

Each of the first and second RF power generating units 61 and 63 may be connected to the plasma generating portion 3. For example, the first RF power generating unit 61 may supply a first RF power to the plasma generating portion 3. The second RF power generating unit 63 may supply a second RF power to the plasma generating portion 3. If the RF power is applied to the plasma generating portion 3, the plasma may be generated in the process space 1h. This will be described in more detail below according to one or more example embodiments.

The third RF power generating unit 4 may supply a third RF power to the stage 7. The third RF power may be used to control the plasma in the process space 1h. This will be described in more detail below.

The gas supplying device GS may be configured to supply the process gas into the process space 1h. According to one or more example embodiments, the gas supplying device GS may include a gas tank, a compressor, and/or at least one valve. A portion of the process gas, which is supplied into the process space 1h by the gas supplying device GS, may be used to form the plasma.

The vacuum pump VP may be connected to the process space 1h. The vacuum pump VP may be used to maintain the process space 1h at a vacuum pressure, during the fabrication process on the substrate.

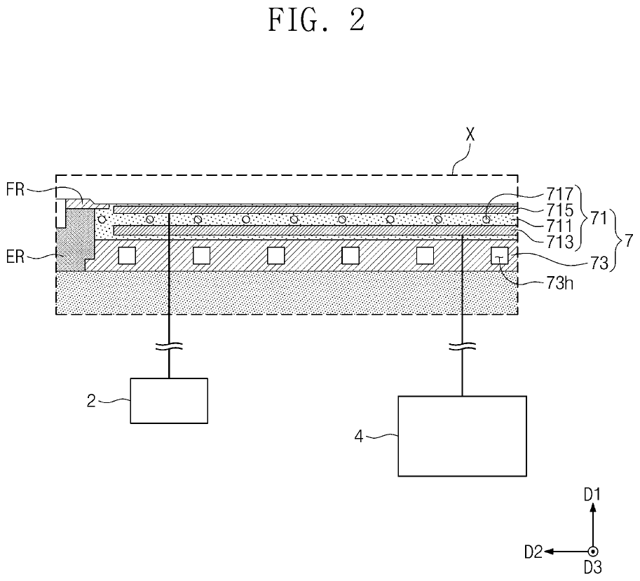

FIG. 2 is an enlarged sectional view illustrating a portion ‘X’ of FIG. 1 according to one or more example embodiments.

Referring to FIG. 2, the stage 7 may include a chuck 71 and a cooling plate 73.

A substrate may be disposed on the chuck 71. The chuck 71 may be configured to fasten the substrate to a specific position. According to one or more example embodiments, the chuck 71 may include a chuck body 711, a plasma electrode 713, a chuck electrode 715, and a heater 717.

The chuck body 711 may be shaped as a circular pipe or cylinder. The chuck body 711 may comprise a ceramic material, but one or more example embodiments are not limited to this example embodiment. The substrate may be disposed on a top surface of the chuck body 711. A focus ring FR and/or an edge ring ER may be provided to enclose the chuck body 711.

The plasma electrode 713 may be placed in the chuck body 711. The plasma electrode 713 may comprise aluminum (Al) or the like. The plasma electrode 713 may have a circular-plate shape, but one or more example embodiments are not limited to this example embodiment. An RF power may be applied to the plasma electrode 713. More specifically, a third RF power may be applied to the plasma electrode 713 by the third RF power generating unit 4. Plasma in the process space 1h (e.g., see FIG. 1) may be controlled by the third RF power applied to the plasma electrode 713.

The chuck electrode 715 may be placed in the chuck body 711. The chuck electrode 715 may be placed over the plasma electrode 713. A DC power may be applied to the chuck electrode 715. More specifically, the DC power may be applied to the chuck electrode 715 by the DC power generating unit 2. The substrate on the chuck body 711 may be fastened to a specific position by the DC power applied to the chuck electrode 715. In one or more example embodiments, the chuck electrode 715 may comprise aluminum (Al), but one or more example embodiments are not limited to this example embodiment.

The heater 717 may be placed in the chuck body 711. The heater 717 may be placed between the chuck electrode 715 and the plasma electrode 713. The heater 717 may include a heating line. For example, the heater 717 may include a heating line, which is provided in a concentric manner. The heater 717 may dissipate heat energy toward neighboring elements. Accordingly, the chuck body 711 or the like may be heated.

The cooling plate 73 may be placed below the chuck 71. In other words, the chuck 71 may be placed on the cooling plate 73. The cooling plate 73 may be configured to have a cooling hole 73h. Cooling water may flow through the cooling hole 73h. The cooling water in the cooling hole 73h may absorb heat energy from the cooling plate 73.

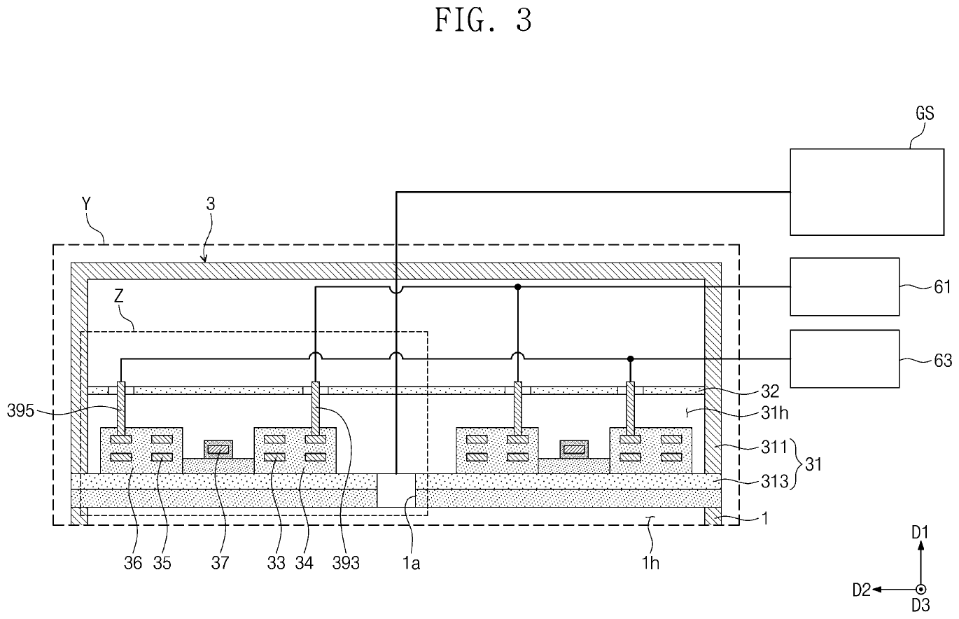

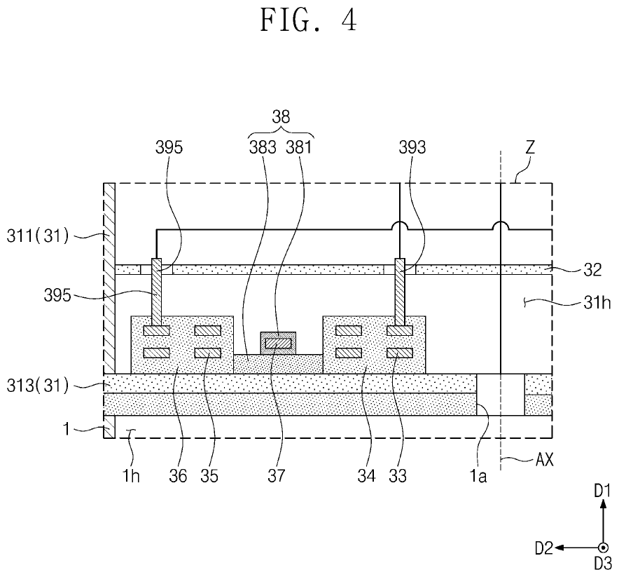

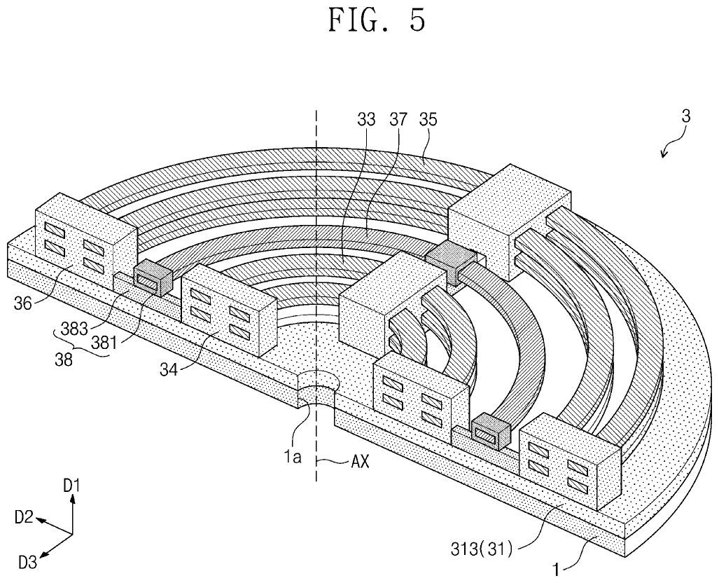

FIG. 3 is an enlarged sectional view illustrating a portion ‘Y’ of FIG. 1, FIG. 4 is an enlarged sectional view illustrating a portion ‘Z’ of FIG. 3, and FIG. 5 is a perspective view partially illustrating a plasma generating portion according to one or more example embodiments.

Referring to FIGS. 3, 4 and 5, the plasma generating portion 3 may include a coil chamber 31, a separation plate 32, an inner antenna ring 33, an outer antenna ring 35, a floating ring 37, a first insulating member 38, a second insulating member 34, a third insulating member 36, a first power delivery rod 393, and a second power delivery rod 395.

The coil chamber 31 may be placed on the process chamber 1. The coil chamber 31 may be configured to provide an upper space 31h. The upper space 31h may be provided over the process space 1h. The upper space 31h may be connected to the process space 1h through an upper hole 1a, but one or more example embodiments are not limited to this example embodiment. The coil chamber 31 may include a supporting plate 313 and a chamber housing 311. The supporting plate 313 may be placed on the process chamber 1. The supporting plate 313 may comprise at least one of conductive or insulating materials. The chamber housing 311 may be placed on the supporting plate 313.

The separation plate 32 may be placed in the coil chamber 31. The inner antenna ring 33, the outer antenna ring 35, the floating ring 37, the first insulating member 38, the second insulating member 34, and the third insulating member 36 may be placed below the separation plate 32.

The inner antenna ring 33 may be placed in the coil chamber 31. The inner antenna ring 33 may be centered on a first axis that extends in the first direction D1. For example, the first axis may coincide with a center axis AX. The inner antenna ring 33 may be shaped like a ring whose center is located on the first axis. The inner antenna ring 33 may comprise at least one of metallic materials. For example, the inner antenna ring 33 may comprise copper (Cu) and/or silver (Ag). More specifically, the inner antenna ring 33 may include a copper pattern plated with silver (Ag). In one or more example embodiments, inner antenna rings 33 may be provided. The inner antenna rings 33 may be spaced apart from each other in the second direction D2 and/or the first direction D1. In one or more example embodiments, the inner antenna rings 33 may be connected to each other. However, in order to reduce complexity in the description, one of the inner antenna rings 33 will be described according to one or more example embodiments.

The outer antenna ring 35 may be placed in the coil chamber 31. The outer antenna ring 35 may be placed outside the inner antenna ring 33. The outer antenna ring 35 may be provided to enclose the inner antenna ring 33, when viewed in a plan view. The outer antenna ring 35 may be spaced apart from the inner antenna ring 33 in an outward direction. In other words, the outer antenna ring 35 and the inner antenna ring 33 may not be in contact with each other. The outer antenna ring 35 may be centered on a second axis, which extends in the first direction D1. For example, the second axis may coincide with the center axis AX. That is, the inner and outer antenna rings 33 and 35 may have the same axis. The outer antenna ring 35 may be shaped like a ring whose center is located on the second axis. The outer antenna ring 35 may comprise at least one of metallic materials. For example, the outer antenna ring 35 may comprise at least one of copper (Cu) and/or silver (Ag). More specifically, the outer antenna ring 35 may include a copper pattern plated with silver (Ag). In one or more example embodiments, a plurality of outer antenna rings 35 may be provided. The outer antenna rings 35 may be spaced apart from each other in the second direction D2 and/or the first direction D1. In one or more example embodiments, the outer antenna rings 35 may be connected to each other. However, in order to reduce complexity in the description, one of the outer antenna rings 35 will be described according to one or more example embodiments.

The floating ring 37 may be placed between the inner antenna ring 33 and the outer antenna ring 35. The floating ring 37 may be spaced apart from the inner antenna ring 33 in an outward direction extending outward from the center axis AX. The floating ring 37 may be spaced apart from the outer antenna ring 35 in an inward direction extending inward toward the center axis AX. The floating ring 37 may not be in contact with the inner antenna ring 33 or the outer antenna ring and 35. The floating ring 37 may be electrically isolated from the inner antenna ring 33 and the outer antenna ring 35. In one or more example embodiments, the floating ring 37 may not be in contact with any conductive material. The floating ring 37 may be in contact with only an insulating material. In other words, the floating ring 37 may be supported by only the insulating material. For example, the floating ring 37 may be supported by only the first insulating member 38. The floating ring 37 may be centered on a third axis, which is extended in the first direction D1. In one or more example embodiments, the third axis may coincide with the center axis AX. In other words, the floating ring 37 may have the same axis as the inner antenna ring 33 and/or the outer antenna ring 35. The floating ring 37 may be shaped as a revolving body centered on the third axis. For example, the floating ring 37 may have a shape of a continuous ring. That is, the floating ring 37 may have a shape of a perfect ring without any cut portion. The floating ring 37 may have a closed-loop shape. The floating ring 37 may have a rectangular section. However, one or more example embodiments are not limited to this example embodiment, and in one or more example embodiments, the section of the floating ring 37 may have a circular shape. The floating ring 37 may comprise at least one of copper (Cu) and/or silver (Ag). More specifically, the floating ring 37 may include a copper pattern plated with silver (Ag). A difference between a level of the floating ring 37 and a level of the inner antenna ring 33 may be less than or equal to 30 mm. For example, a center of the floating ring 37 may be located at a level that is higher than a center of the inner antenna ring 33 by a distance ranging from 0 mm to 30 mm. Alternatively, the center of the floating ring 37 may be located at a level that is lower than the center of the inner antenna ring 33 by a distance ranging from 0 mm to 30 mm. The level of the floating ring 37 may be changed. This will be described in more detail below according to one or more example embodiments.

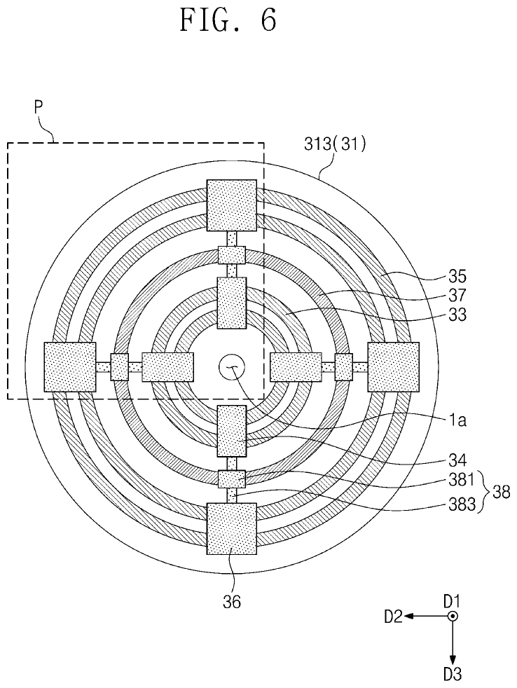

The first insulating member 38 may support the floating ring 37. The first insulating member 38 may be in contact with the floating ring 37. The floating ring 37 may not be in contact with any material other than the first insulating member 38. In other words, the floating ring 37 may not be in contact with any solid material other than the first insulating member 38. The floating ring 37 may be provided to penetrate the first insulating member 38. That is, the first insulating member 38 may be provided to enclose a portion of the floating ring 37. The first insulating member 38 may comprise at least one of insulating materials. For example, the first insulating member 38 may comprise at least one of plastic materials. More specifically, the first insulating member 38 may comprise polyether ether ketone (PEEK). In one or more example embodiments, a plurality of the first insulating members 38 may be provided. The first insulating members 38 may be spaced apart from each other in a circumferential direction. For example, four first insulating members 38 may be spaced apart from each other in the circumferential direction, as shown in FIGS. 5 and 6. However, in order to reduce complexity in the description, one of the first insulating members 38 will be described according to one or more example embodiments. The first insulating member 38 may include a supporting insulating member 381 and a connection insulating member 383.

The supporting insulating member 381 may be in contact with the floating ring 37 and may support the floating ring 37. The floating ring 37 may be provided to penetrate the supporting insulating member 381. Thus, the supporting insulating member 381 may enclose a portion of the floating ring 37.

The connection insulating member 383 may be placed below the supporting insulating member 381. The connection insulating member 383 may support the supporting insulating member 381. The connection insulating member 383 may extend in a radial direction. The connection insulating member 383 may be connected to the second insulating member 34 and the third insulating member 36.

The second insulating member 34 may support the inner antenna ring 33. The second insulating member 34 may be in contact with the inner antenna ring 33. The inner antenna ring 33 may be provided to penetrate the second insulating member 34. The second insulating member 34 may enclose a portion of the inner antenna ring 33. The second insulating member 34 may comprise at least one of insulating materials. For example, the second insulating member 34 may comprise at least one of plastic materials. More specifically, the second insulating member 34 may comprise polyether ether ketone (PEEK). In one or more example embodiments, a plurality of second insulating members 34 may be provided. The second insulating members 34 may be spaced apart from each other in a circumferential direction. However, in order to reduce complexity in the description, one of the second insulating members 34 will be described according to one or more example embodiments.

The third insulating member 36 may support the outer antenna ring 35. The third insulating member 36 may be in contact with the outer antenna ring 35. The outer antenna ring 35 may be provided to penetrate the third insulating member 36. The third insulating member 36 may enclose a portion of the outer antenna ring 35. The third insulating member 36 may comprise at least one of insulating materials. For example, the third insulating member 36 may comprise at least one of plastic materials. More specifically, the third insulating member 36 may comprise polyether ether ketone (PEEK). In one or more example embodiments, a plurality of third insulating members 36 may be provided. The third insulating members 36 may be spaced apart from each other in a circumferential direction. However, in order to reduce complexity in the description, one of the third insulating members 36 will be described according to one or more example embodiments.

The first power delivery rod 393 may be coupled to the inner antenna ring 33. For example, the first power delivery rod 393 may extend from the inner antenna ring 33 in an upward direction. The first power delivery rod 393 may electrically connect the inner antenna ring 33 to the first RF power generating unit 61. The first power delivery rod 393 may be used to supply a first RF power to the inner antenna ring 33.

The second power delivery rod 395 may be coupled to the outer antenna ring 35. For example, the second power delivery rod 395 may extend from the outer antenna ring 35 in an upward direction. The second power delivery rod 395 may electrically connect the outer antenna ring 35 to the second RF power generating unit 63. The second power delivery rod 395 may supply a second RF power to the outer antenna ring 35.

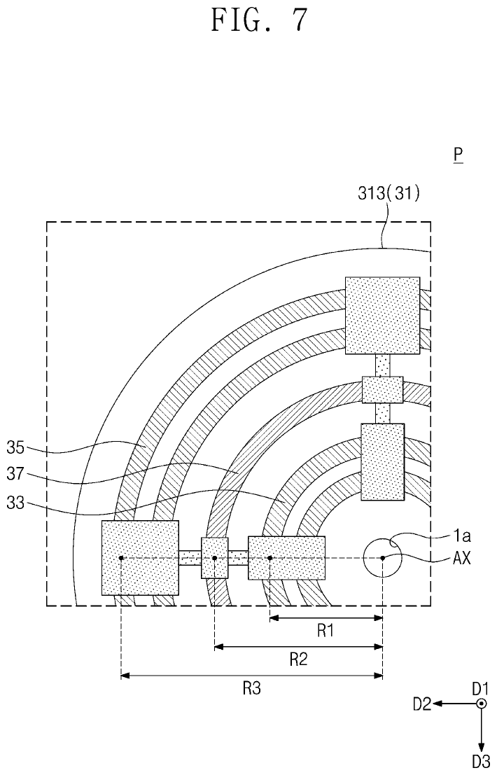

FIG. 6 is a plan view illustrating a plasma generating portion according to one or more example embodiments, and FIG. 7 is an enlarged plan view illustrating ‘P’ of FIG. 6 according to one or more example embodiments.

Referring to FIGS. 6 and 7, a radius of the inner antenna ring 33 may be referred to as a first radius R1. The first radius R1 may range from about 75 mm to about 100 mm. More specifically, the first radius R1 may be about 90 mm. In one or more example embodiments where a plurality of inner antenna rings 33 are provided, a radius of each of the inner antenna rings 33 may range from about 75 mm to about 100 mm.

A radius of the outer antenna ring 35 may be referred to as a third radius R3. The third radius R3 may be larger than the first radius R1. The third radius R3 may range from about 160 mm to about 250 mm. More specifically, the third radius R3 may be about 225 mm. In one or more example embodiments where a plurality of outer antenna rings 35 are provided, a radius of each of the outer antenna ring 35 may range from about 160 mm to about 250 mm.

A radius of the floating ring 37 may be referred to as a second radius R2. The second radius R2 may be larger than the first radius R1. The second radius R2 may be smaller than the third radius R3. The second radius R2 may range from about 90 mm to about 155 mm. More specifically, the radius of the floating ring 37 may be about 140 mm. However, one or more example embodiments are not limited to this example embodiment.

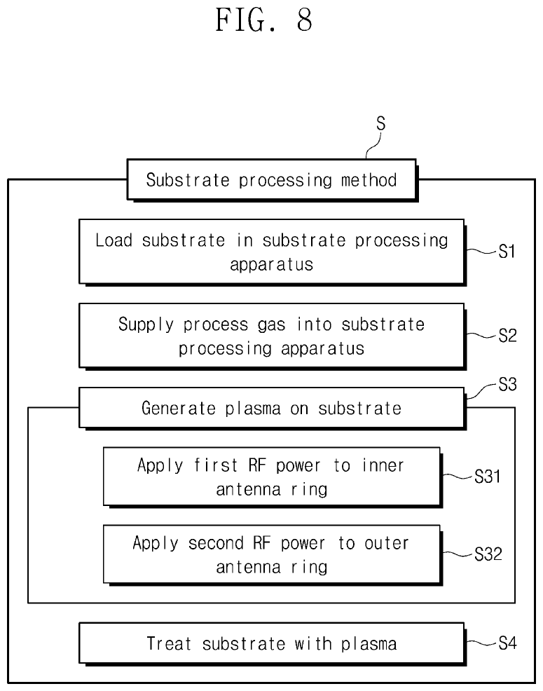

FIG. 8 is a flow chart illustrating a substrate processing method according to one or more example embodiments.

Referring to FIG. 8, a substrate processing method S may be provided. The substrate processing method S may be used in a process of treating a substrate using the substrate process apparatus A described with reference to FIGS. 1, 2, 3, 4, 5, 6 and 7. The substrate processing method S may include loading a substrate in a substrate processing apparatus (in S1), supplying a process gas into the substrate processing apparatus (in S2), generating plasma on the substrate (in S3), and treating the substrate with the plasma (in S4).

The generating of the plasma on the substrate (in S3) may include applying a first RF power to an inner antenna ring (in S31) and applying a second RF power to an outer antenna ring (in S32).

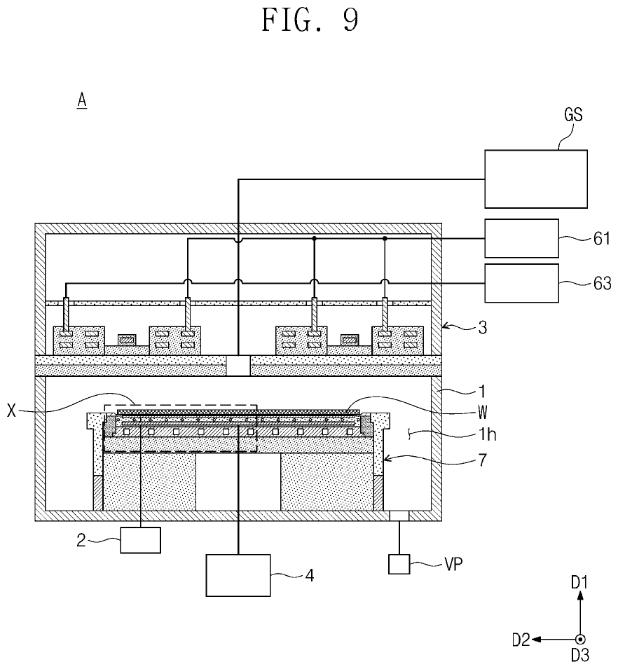

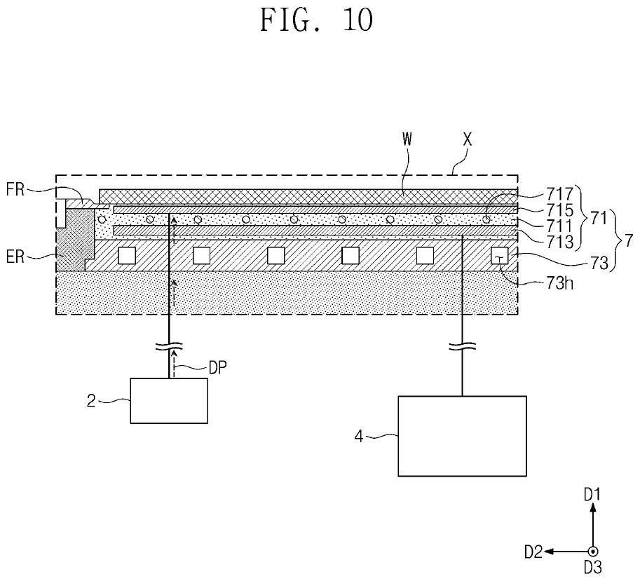

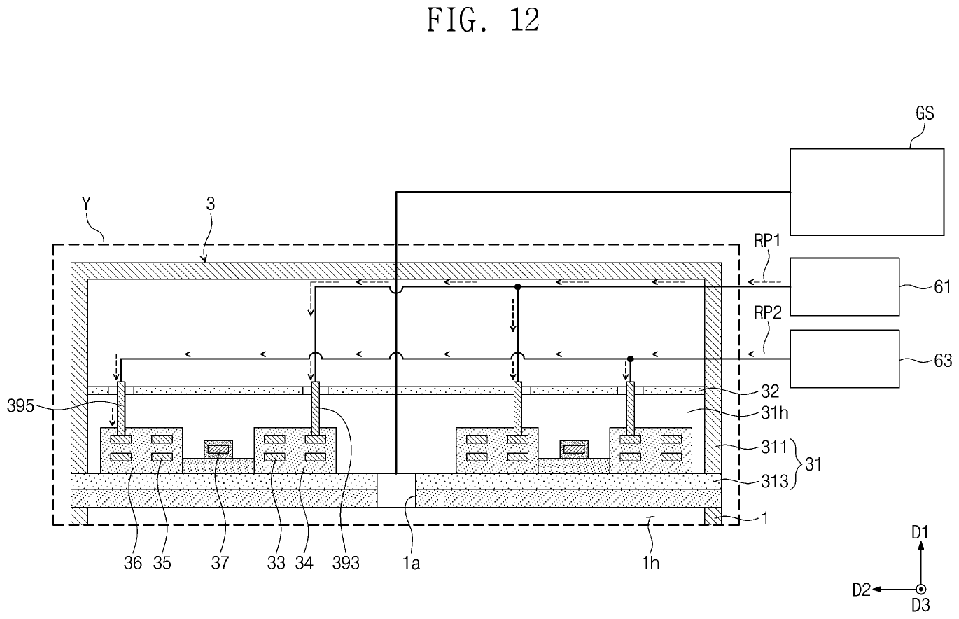

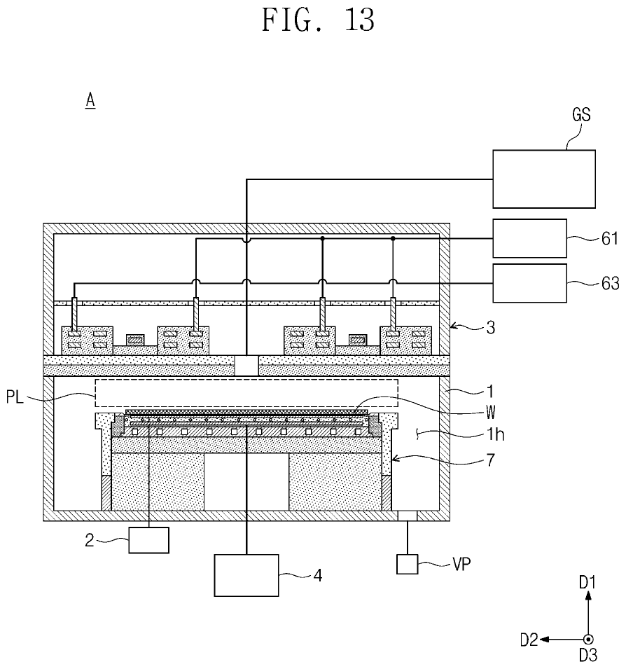

Hereinafter, the substrate processing method S of FIG. 8 will be described in more detail with reference to one or more example embodiments shown in FIGS. 9, 10, 11, 12, 13 and 14.

FIGS. 9, 10, 11, 12, 13 and 14 are diagrams illustrating a substrate processing method according to the flow chart of FIG. 8 according to one or more example embodiments.

Referring to FIGS. 9, 10, and 8, the loading of the substrate in the substrate processing apparatus (in S1) may include placing a substrate W on the chuck 71. If a DC power DP is applied to the chuck electrode 715 from the DC power generating unit 2, the substrate W may be fastened to a specific position on the chuck body 711 by the chuck electrode 715.

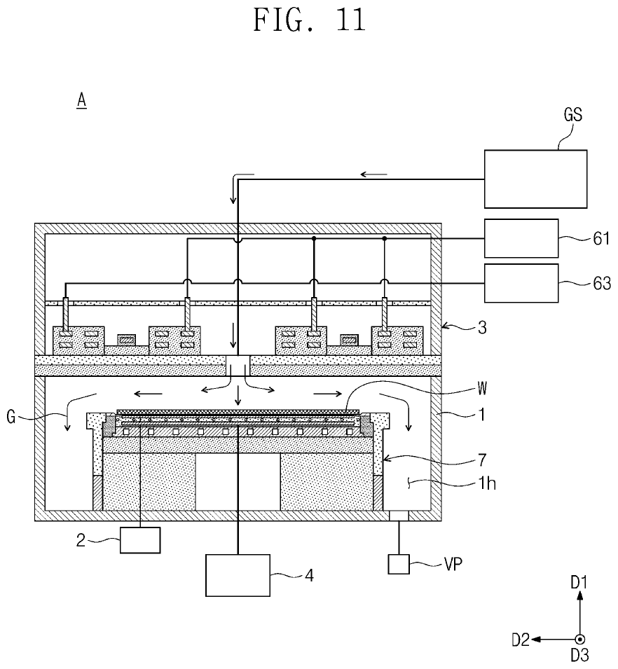

Referring to FIGS. 11 and 8, the supplying of the process gas into the substrate processing apparatus (in S2) may include supplying a process gas G into the process space 1h using the gas supplying device GS.

Referring to FIGS. 12, 13, and 8, the applying of the first RF power to the inner antenna ring (in S31) may include applying a first RF power RP1, which is generated by the first RF power generating unit 61, to the inner antenna ring 33 through the first power delivery rod 393. The applying of the second RF power to the outer antenna ring (in S32) may include applying a second RF power RP2, which is generated by the second RF power generating unit 63, to the outer antenna ring 35 through the second power delivery rod 395. An electric field and/or a magnetic field may be produced in the process space 1h by the RF powers applied to the inner and outer antenna rings 33 and 35. Thus, plasma PL may be produced from at least a portion of the process gas G, which is supplied into the process space 1h. In this process, no power may be applied to the floating ring 37. That is, the RF power may be applied to only the inner and outer antenna rings 33 and 35, and the floating ring 37 may not be applied with any RF power.

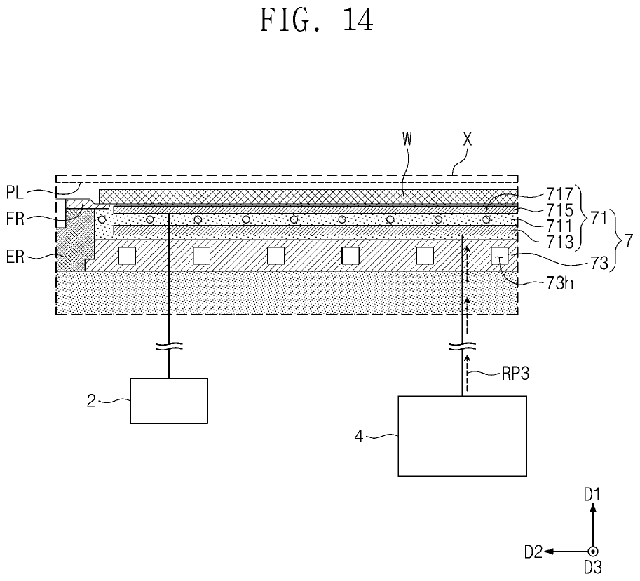

Referring to FIGS. 14 and 8, the treating of the substrate with the plasma (in S4) may include applying a third RF power RP3 to the plasma electrode 713. More specifically, the third RF power RP3 may be applied to the plasma electrode 713 from the third RF power generating unit 4. The third RF power RP3 may be used to control the plasma PL in the process space 1h. For example, particles in the plasma PL may be moved toward the substrate W by the third RF power RP3. Accordingly, the substrate W may be treated.

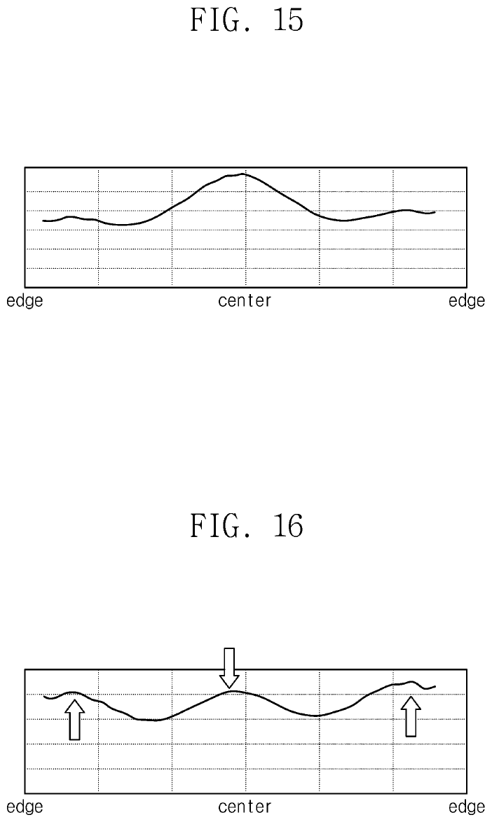

FIGS. 15 and 16 are graphs showing technical effects that can be obtained by a substrate processing apparatus according to one or more example embodiments.

In the graphs of FIGS. 15 and 16, the horizontal axis represents a position on a substrate including a center region and an edge region. The vertical axis represents a strength of an electric field produced on the substrate. FIG. 15 shows a spatial distribution of the electric field produced in the absence of the floating ring. FIG. 15 reveals that, if the floating ring is not used, there is a significant difference in the strength of the electric field between the center and edge regions. FIG. 16 shows a spatial distribution of the electric field produced in the presence of the floating ring. FIG. 16 reveals that, if the floating ring is used, the difference in the strength of the electric field between the center and edge regions is reduced. That is, the use of the floating ring may make it possible to improve the spatial uniformity of the electric field.

In a substrate processing apparatus according to one or more example embodiments and a substrate processing method using the same, a floating ring, which is configured to uniformly produce an electric field in a process space, may be provided. Thus, it may be possible to uniformly generate plasma in the process space. That is, the uniformity of the plasma may be improved. This may make it possible to improve uniformity in a fabrication process performed on a substrate. For example, an etching process on the substrate may be performed with improved etching uniformity. That is, an etch rate in the center region of the substrate may be controlled to be similar to an etch rate in the edge region of the substrate. This may lead to an increase of yield in a fabrication process.

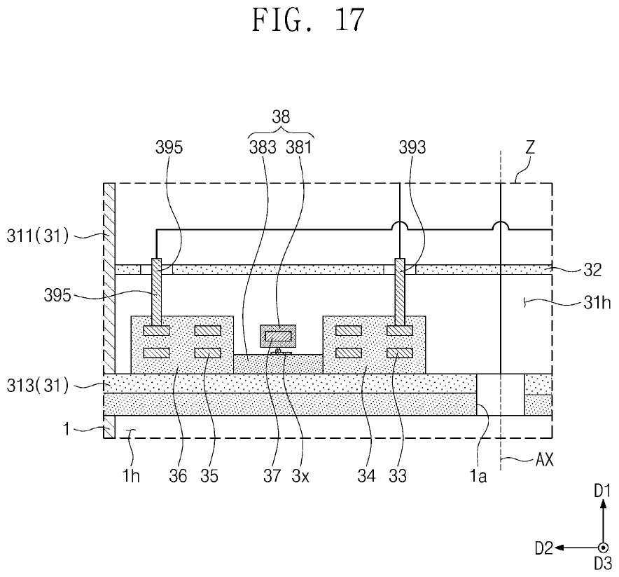

FIG. 17 is a sectional view illustrating a portion of a substrate processing apparatus according to one or more example embodiments.

In the following description, for concise description, an element previously described with reference to FIGS. 1, 2, 3, 4, 5, 6, 7, 8, 9, 10, 11, 12, 13, 14, 15, 16 and 17 may be identified by the same reference number without repeating overlapping duplicate description thereof.

Referring to FIG. 17, the plasma generating portion 3 may further include a floating ring driving unit 3x. The floating ring driving unit 3x may be configured to change a position of the floating ring 37. In one or more example embodiments, the floating ring driving unit 3x may be placed on the connection insulating member 383. The floating ring driving unit 3x may support the supporting insulating member 381. In one or more example embodiments, the floating ring driving unit 3x may be configured to move the supporting insulating member 381 in the first direction D1. Thus, the floating ring 37 may be moved in a vertical direction. Alternatively, the floating ring driving unit 3x may be configured to move the supporting insulating member 381 in a radial direction. Thus, the floating ring 37 may be moved in a horizontal direction. According to one or more example embodiments, the floating ring driving unit 3x may include an actuator, such as a motor or a hydraulic device.

In a substrate processing apparatus according to one or more example embodiments and a substrate processing method using the same, the floating ring may be configured to be movable, if desired. Thus, an electric field generated in a process space may be controlled to have a spatial distribution that is suitable for a fabrication process. As a result, the substrate processing apparatus may be adaptively used for various processes.

In a substrate processing apparatus according to one or more example embodiments and a substrate processing method using the same, it may be possible to improve uniformity of plasma.

In a substrate processing apparatus according to one or more example embodiments and a substrate processing method using the same, it may be possible to uniformly perform a fabrication process on a substrate.

In a substrate processing apparatus according to one or more example embodiments and a substrate processing method using the same, the substrate processing apparatus may be adaptively used for various processes.

While one or more example embodiments have been particularly shown and described above, it will be apparent to those of ordinary skill in the art that variations in form and detail may be made therein without departing from the spirit and scope of the following claims.

1. A substrate processing apparatus comprising:
a process chamber providing a process space; and
a plasma generator on the process chamber,
wherein the plasma generator comprises:
an inner antenna ring;
an outer antenna ring outside of and spaced apart from the inner antenna ring; and
a floating ring between the inner antenna ring and the outer antenna ring, and
wherein the floating ring is electrically isolated from the inner antenna ring and the outer antenna ring.

2. The substrate processing apparatus of claim 1, wherein the plasma generator further comprises a first insulating member contacting the floating ring and supporting the floating ring, and
wherein the floating ring does not contact any material other than the first insulating member.

3. The substrate processing apparatus of claim 2, wherein the floating ring penetrates the first insulating member, and
wherein the first insulating member encloses a portion of the floating ring.

4. The substrate processing apparatus of claim 2, wherein the first insulating member comprises a plurality of first insulating members spaced apart from each other.

5. The substrate processing apparatus of claim 2, wherein the first insulating member comprises polyether ether ketone, and
wherein the floating ring comprises copper.

6. The substrate processing apparatus of claim 1, wherein the plasma generator further comprises:
a first power delivery rod coupled to the inner antenna ring and is configured to deliver a first radio frequency (RF) power to the inner antenna ring; and
a second power delivery rod coupled to the outer antenna ring and configured to deliver a second RF power to the outer antenna ring.

7. The substrate processing apparatus of claim 6, wherein the first power delivery rod extends from the inner antenna ring in an upward direction, and
wherein the second power delivery rod extends from the outer antenna ring in the upward direction.

8. The substrate processing apparatus of claim 1, wherein a radius of the floating ring is in a range of 90 mm to 155 mm.

9. A substrate processing apparatus comprising:
a process chamber; and
a plasma generator on the process chamber,
wherein the plasma generator comprises:
an inner antenna ring;
an outer antenna ring outside of the inner antenna ring;
a floating ring between and electrically isolated from the inner antenna ring and the outer antenna ring;
first power delivery rod connected to the inner antenna ring and configured to deliver a first RF power to the inner antenna ring; and
a second power delivery rod connected to the outer antenna ring and configured to deliver a second RF power to the outer antenna ring, and
wherein the floating ring has a continuous ring shape.

10. The substrate processing apparatus of claim 9, wherein the floating ring does not contact any conductive material.

11. The substrate processing apparatus of claim 9, wherein the plasma generator further comprises a first insulating member contacting and supporting the floating ring.

12. The substrate processing apparatus of claim 11, wherein the plasma generator further comprises:
a second insulating member contacting and supporting the inner antenna ring; and
a third insulating member contacting and supporting the outer antenna ring.

13. The substrate processing apparatus of claim 12, wherein the first insulating member extends in a radial direction and is connected to the second insulating member and the third insulating member.

14. The substrate processing apparatus of claim 9, wherein the floating ring and the inner antenna ring are spaced apart by a distance less than or equal to 30 mm.

15. The substrate processing apparatus of claim 9, wherein a radius of the inner antenna ring is in a range of 75 mm to 100 mm, and
wherein a radius of the outer antenna ring is in a range of 160 mm to 250 mm.

16. A substrate processing apparatus comprising:
a process chamber providing a process space; and
a plasma generator provided above the process space,
wherein the plasma generator comprises:
an inner antenna ring centered on a first axis extending in a first direction;
an outer antenna ring outside of the inner antenna ring and centered on a second axis extending in the first direction; and
a floating ring between the inner antenna ring and the outer antenna ring and centered on a third axis extending in the first direction, and
wherein the floating ring comprises a revolving body centered on the third axis.

17. The substrate processing apparatus of claim 16, wherein the third axis coincides with the first axis.

18. The substrate processing apparatus of claim 16, further comprising:
a plurality of inner antenna rings; and
a plurality of outer antenna rings.

19. The substrate processing apparatus of claim 16, wherein the plasma generator further comprises:
a first power delivery rod coupled to the inner antenna ring and configured to deliver a first radio frequency (RF) power to the inner antenna ring; and
a second power delivery rod coupled to the outer antenna ring and configured to deliver a second RF power to the outer antenna ring.

20. The substrate processing apparatus of claim 19, further comprising:
a first RF power generator configured to supply the first RF power to the first RF power delivery rod; and
a second RF power generator configured to supply the second RF power to the second RF power delivery rod.

21.-25. (canceled)
